(19) United States
(12) Patent Application Publication
(10) Pub. No.: US 2026/0101697 A1
(43) Pub. Date: Apr. 9, 2026

(54) METHOD AND APPARATUS FOR CLEANING WAFER

(71) Applicant: DISCO CORPORATION, Tokyo (JP)

(72) Inventors: Atsushi KOMATSU, Tokyo (JP); Cheng Hsiang WANG, Tokyo (JP)

(21) Appl. No.: 19/329,667

(22) Filed: Sep. 16, 2025

(30) Foreign Application Priority Data
Oct. 3, 2024 (JP) 2024-174075

(51) Int. Cl. H01L 21/67; H01L 21/02; H01L 21/304; H01L 21/687

(52) U.S. Cl. CPC H10P 72/0412; H10P 52/00; H10P 72/0414; H10P 72/7618; H10P 90/128

(57) ABSTRACT

Provided is a method for cleaning a wafer that enables sufficient removal of cutting chips from the wafer surface. The method for cleaning a wafer includes: mounting a wafer 56 on a spinner table 4 such that a rear surface of the wafer 56 faces the spinner table 4 and a front surface 56a of the wafer 56 is exposed, the spinner table 4 being rotatable while holding the wafer 56; subjecting the front surface 56a of the wafer 56 to first cleaning with cleaning water supplied to the front surface 56a of the wafer 56, while rotating the spinner table 4; and subjecting the front surface 56a of the wafer 56 to second cleaning with ammonia water supplied to the front surface 56a of the wafer 56 using a brush. [Elected View] FIG. 6

### BACKGROUND

### 1. Technical Field

The present disclosure relates to a method and an apparatus for cleaning a wafer that has on its front surface a device region where a plurality of devices are demarcated by division lines.

### 2. Description of the Related Art

A wafer that has on its front surface a device region where a plurality of devices, such as ICs and LSIs, are demarcated by division lines is ground on the rear surface and thinned, and then is diced into individual device chips by a dicing apparatus, a laser processing apparatus and the like. The resulting device chips are used in electronic appliances, such as portable phones and personal computers.

On the outer periphery of the wafer, a chamfered portion is formed to surround the device region, and when the wafer is ground on the rear surface and thinned, the chamfered portion assumes a sharp knife-edge shape. As such, the wafer requires especially careful handling. Further, when the chamfered portion assumes a sharp knife-edge shape, cracks are likely to be initiated from the outer periphery of the wafer and propagate inward, leading to a higher risk of damage to the devices. To address these problems, a technique has been proposed to remove the necessary amount of chamfered portion in advance so that the wafer does not assume a knife-edge shape on the outer periphery when it is thinned (see JP2022-178899A).

### SUMMARY

However, when the chamfered portion of the wafer is cut using a cutting blade while being supplied with cutting water, cutting chips adhere to the wafer surface and contaminate the device region. The cutting chips that have adhered to the wafer surface may not be sufficiently removed by cleaning with high-pressure water or a binary fluid mixture of high-pressure water and high-pressure air, and if the cutting chips remain on the wafer surface, they could lead to a serious problem especially in wafer lamination technology.

It is an object of the present disclosure to provide a method and an apparatus for cleaning a wafer that enable sufficient removal of cutting chips from the wafer surface.

To achieve the aforementioned object, the present disclosure provides the following method for cleaning a wafer: “A method for cleaning a wafer that has on its front surface a device region where a plurality of devices are demarcated by a division line, the method including: mounting the wafer on a spinner table such that a rear surface of the wafer faces the spinner table and a front surface of the wafer is exposed, the spinner table being rotatable while holding the wafer; subjecting the front surface of the wafer to first cleaning with cleaning water supplied to the front surface of the wafer, while rotating the spinner table; and subjecting the front surface of the wafer to second cleaning with ammonia water supplied to the front surface of the wafer using a brush.”

Preferably, the method further includes, after the second cleaning, subjecting the front surface of the wafer to third final cleaning with pure water supplied to the front surface of the wafer. It is desirable that the method further includes, before the first cleaning, removing a necessary amount of chamfered portion using a cutting blade, while supplying cutting water to the chamfered portion, the chamfered portion being formed on an outer periphery of the wafer to surround the device region.

To achieve the aforementioned object, the present disclosure provides the following apparatus for cleaning a wafer: “A cleaning apparatus for performing the above-described method, the apparatus including: the spinner table; a cleaning water supply unit including a cleaning nozzle that supplies the cleaning water to the front surface of the wafer held on the spinner table; and an ammonia cleaning unit that cleans the front surface of the wafer held on the spinner table with the ammonia water supplied to the front surface of the wafer using the brush.”

According to the present disclosure, the method for cleaning a wafer that has on its front surface a device region where a plurality of devices are demarcated by a division line includes: mounting the wafer on a spinner table such that a rear surface of the wafer faces the spinner table and a front surface of the wafer is exposed, the spinner table being rotatable while holding the wafer; subjecting the front surface of the wafer to first cleaning with cleaning water supplied to the front surface of the wafer, while rotating the spinner table; and subjecting the front surface of the wafer to second cleaning with ammonia water supplied to the front surface of the wafer using a brush. Thus, the surface of the wafer can be sufficiently cleared of cutting chips.

Further, according to the present disclosure, the cleaning apparatus for performing the above-described method includes: the spinner table; a cleaning water supply unit including a cleaning nozzle that supplies the cleaning water to the front surface of the wafer held on the spinner table; and an ammonia cleaning unit that cleans the front surface of the wafer held on the spinner table with the ammonia water supplied to the front surface of the wafer using the brush. Thus, the surface of the wafer can be sufficiently cleared of cutting chips.

### BRIEF DESCRIPTION OF THE DRAWINGS

FIG. 1 is a perspective view of a cleaning apparatus according to the present disclosure;

FIG. 2 is a perspective view of a wafer held by suction on a chuck table of a cutting apparatus;

FIG. 3A is a schematic view illustrating removal of a chamfered portion, and FIG. 3B is a perspective view of the wafer from which the chamfered portion has been removed;

FIG. 4 is a plan view illustrating mounting;

FIG. 5 is a plan view illustrating first cleaning;

FIG. 6 is a plan view illustrating second cleaning;

FIG. 7 is a plan illustrating third cleaning; and

FIG. 8 is a plan view illustrating drying.

### DETAILED DESCRIPTION

Preferred embodiments of a method and an apparatus for cleaning a wafer according to the present disclosure will be described with reference to the drawings.

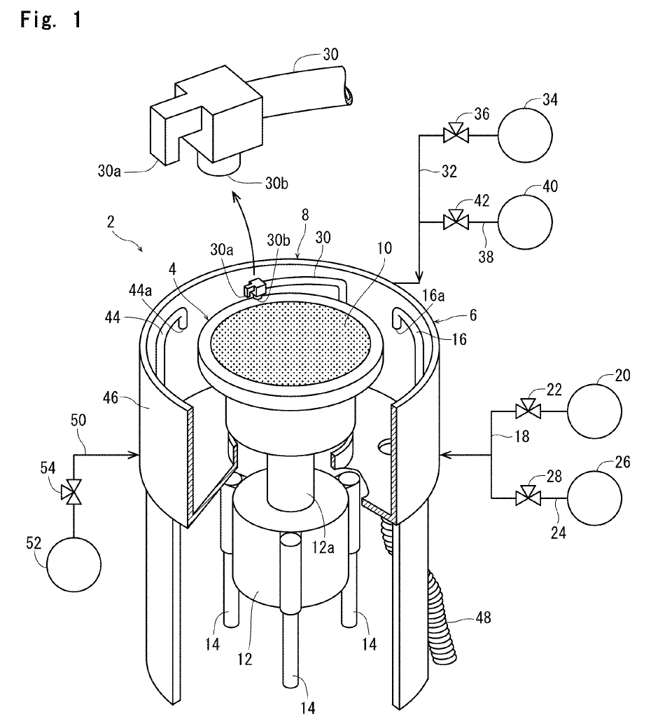

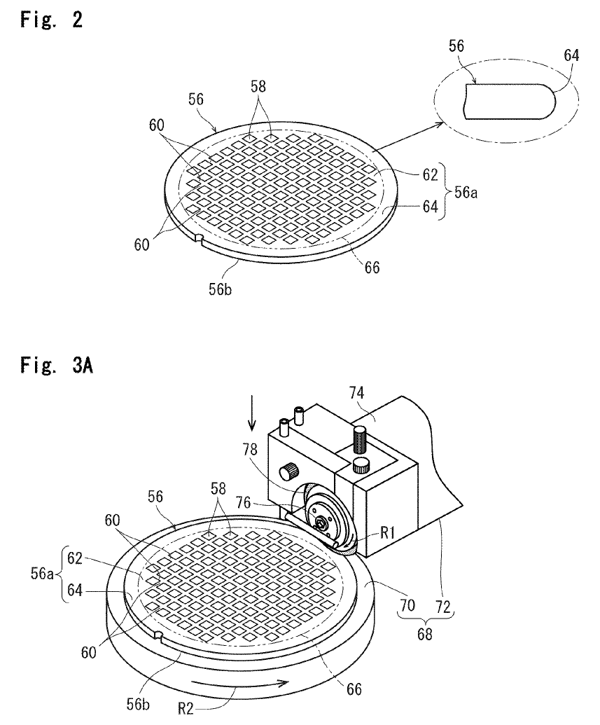

Cleaning apparatus 2 A cleaning apparatus 2 will be described with reference to FIG. 1. The cleaning apparatus 2 includes a spinner table 4 that is rotated while holding a wafer, a cleaning water supply unit 6 with a cleaning nozzle that supplies cleaning water to the surface of the wafer held on the spinner table 4, and an ammonia cleaning unit 8 that cleans the wafer surface with ammonia water using a brush.

Spinner table 4 of cleaning apparatus 2 A circular suction chuck 10 is arranged at the upper end of the spinner table 4. The suction chuck 10 is made of a porous material such as porous ceramics. The suction chuck 10 is connected to a suction unit (not illustrated). The spinner table 4 holds the wafer placed on the upper surface of the suction chuck 10 by suction created by the suction unit on the upper surface of the suction chuck 10.

The spinner table 4 is connected in its central part to an output shaft 12a of a motor 12 that rotates the spinner table 4. The motor 12 rotates the spinner table 4 around an axis that extends in the vertical direction. A lifting and lowering unit 14, which can be composed of an actuator such as an air cylinder, is mounted on the outer peripheral surface of the motor 12. The lifting and lowering unit 14 lifts and lowers the spinner table 4 between a lifted position (as illustrated in FIG. 1) where the wafer is attached/detached and a lowered position (not illustrated) where the wafer is cleaned.

Cleaning water supply unit 6 of cleaning apparatus 2 The cleaning water supply unit 6 includes a cleaning nozzle 16 that supplies cleaning water to the surface of the wafer held on the spinner table 4, and a motor (not illustrated) that swings the cleaning nozzle 16. The cleaning nozzle 16 is connected to a high-pressure pure water source 20 via a conduit 18. The conduit 18 includes an on-off valve 22. The cleaning water supply unit 6 supplies pure water from the high-pressure pure water source 20 as the cleaning water to the surface of the wafer on the spinner table 4 through a spray orifice 16a of the cleaning nozzle 16 that is being swung.

The cleaning nozzle 16 of the present embodiment is also connected to a high-pressure air source 26 via a conduit 24. The conduit 24 includes an on-off valve 28. Thus, the cleaning water supply unit 6 is also capable of supplying a binary fluid mixture of pure water from the high-pressure pure water source 20 and high-pressure air from the high-pressure air source 26 as the cleaning water to the surface of the wafer on the spinner table 4 through the spray orifice 16a of the cleaning nozzle 16 that is being swung.

Ammonia cleaning unit 8 of cleaning apparatus 2 The ammonia cleaning unit 8 includes an ammonia water nozzle 30 that supplies ammonia water to the surface of the wafer held on the spinner table 4, and a motor (not illustrated) that swings the ammonia water nozzle 30. As illustrated in magnification in FIG. 1, the ammonia water nozzle 30 includes at its front edge a spray orifice 30a through which the ammonia water is sprayed to the wafer on the spinner table 4, and a brush 30b for cleaning the wafer surface. The brush 30b can be made of an appropriate synthetic resin material such as polyvinyl alcohol (PVA). The ammonia water nozzle 30 is connected to an ammonia water source 34 via a conduit 32. The conduit 32 includes an on-off valve 36. The ammonia cleaning unit 8 supplies ammonia water from the ammonia water source 34 to the surface of the wafer on the spinner table 4 through the spray orifice 30a of the ammonia water nozzle 30 that is being swung, and cleans the wafer surface using the brush 30b.

The ammonia water nozzle 30 of the present embodiment is also connected to a high-pressure air source 40 via a conduit 38. The conduit 38 includes an on-off valve 42. Thus, the ammonia cleaning unit 8 is also capable of supplying a binary fluid mixture of ammonia water from the ammonia water source 34 and high-pressure air from the high-pressure air source 40 as the ammonia water to the surface of the wafer on the spinner table 4 through the spray orifice 30a of the ammonia water nozzle 30 that is being swung, so that the wafer surface can be cleaned with this ammonia water using the brush 30b.

The cleaning apparatus 2 further includes an air nozzle 44 that supplies dry air to the surface of the wafer held on the spinner table 4, a motor (not illustrated) that swings the air nozzle 44, a drain pan 46 that receives the cleaning water and the ammonia water, and a drain hose 48

that drains the cleaning water and the ammonia water received by the drain pan 46. The air nozzle 44 is connected to a high-pressure air source 52 via a conduit 50. The conduit 50 includes an on-off valve 54.

Wafer 56FIG. 2 illustrates a disc-shaped wafer 56 that can be cleaned by the cleaning method of the present embodiment. The wafer 56 can be made of an appropriate semiconductor material such as silicon. The wafer 56 has on its front surface 56a a device region 62 where a plurality of devices 58, such as ICs and LSIs, are demarcated by lattice-like division lines 60. On the outer periphery of the wafer 56, a chamfered portion 64 is formed to surround the device region 62. For descriptive purposes, a ring-shaped boundary 66 between the device region 62 and the chamfered portion 64 is shown by the dash-dot-dot line; however, there actually exists no such line marking the boundary 66.

Removal of chamfered portion In the present embodiment, before the cleaning of the wafer 56 using the cleaning apparatus 2, the necessary amount of the chamfered portion 64 of the wafer 56 is removed using a cutting blade, while cutting water is supplied to the chamfered portion 64.

Cutting apparatus 68 The chamfered portion 64 can be removed using, for example, a cutting apparatus 68 illustrated in FIG. 3A. The cutting apparatus 68 includes a chuck table 70 that holds the wafer 56 by suction, and a cutting unit 72 that cuts the wafer 56 held by suction on the chuck table 70. The chuck table 70 is configured to be rotatable around an axis in the vertical direction while holding the wafer 56 by suction on its upper surface. The cutting unit 72 includes a spindle housing 74, a spindle 76 supported rotatably in the spindle hosing 74, and an annular cutting blade 78 fixed to the front edge of the spindle 76. The cutting blade 78 is made from abrasive grains, such as diamond, and a binder, such as metal or resin, to have a predetermined thickness.

For removal of the chamfered portion 64, initially, the wafer 56 is held on the upper surface of the chuck table 70 by suction such that the front surface 56a of the wafer 56 faces upward. Then, the wafer 56 is imaged from above by an imaging unit (not illustrated) of the cutting apparatus 68, and the cutting blade 78 is placed against the chamfered portion 64 of the wafer 56 based on the image of the wafer 56 took by the imaging unit. Thereafter, the tip of the cutting blade 78 rotated rapidly in the direction indicated by the arrow R1 is allowed to cut into the chamfered portion 64 of the wafer 56 to a predetermined depth, while cutting water is supplied to the site to be cut with the tip of the cutting blade 78; meanwhile, the chuck table 70 is rotated in the direction indicated by the arrow R2. Thus, the necessary amount of the chamfered portion 64 can be removed. FIG. 3B illustrates the wafer 56 from which the chamfered portion 64 has been removed, creating a space represented by reference numeral 80.

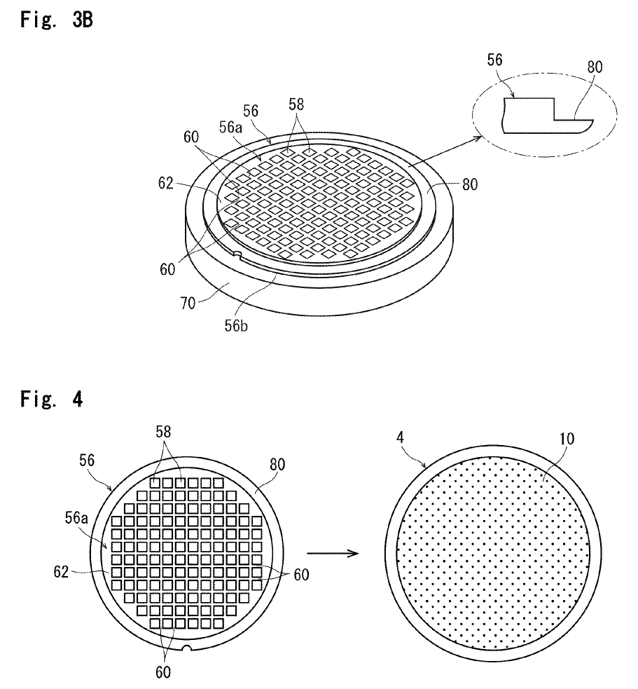

Mounting After the removal of the chamfered portion 64, the wafer 56 is mounted on the spinner table 4 of the cleaning apparatus 2 such that a rear surface 56b of the wafer 56 faces the spinner table 4 and the front surface 56a is exposed, as shown in FIG. 4. More specifically, the wafer 56 is placed on the spinner table 4 with its front surface 56a facing upward and is then held by suction that is created on the upper surface of the suction chuck 10 of the spinner table 4 and acts on the rear surface 56b of the wafer 56. During mounting of the wafer 56, the spinner table 4 is kept located at the lifted position (as illustrated in FIG. 1). Each of the cleaning nozzle 16, the ammonia water nozzle 30, and the air nozzle 44 is kept located at a standby position (as illustrated in FIG. 1), which is not directly above the spinner table 4.

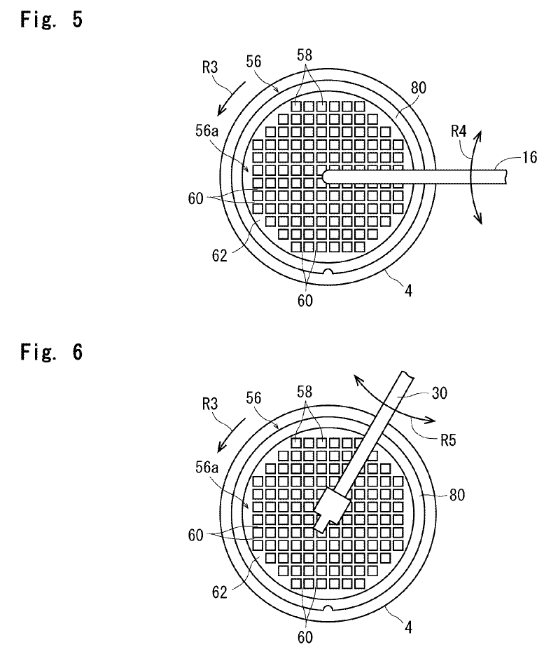

First cleaning The wafer 56 mounted as described above is then subjected to first cleaning with the cleaning water supplied to the front surface 56a of the wafer 56, while the spinner table 4 is rotated. More specifically, initially, the spinner table 4 is located at the lowered position by the lifting and lowering unit 14. Then, a lid (not illustrated) is put on the upper edge of the drain pan 46 to prevent spattering of the cleaning water and the ammonia water. Subsequently, the spinner table 4 is rotated in the direction indicated by the arrow R3 in FIG. 5 at a predetermined speed (e.g., 800 rpm). Thereafter, the cleaning water is supplied to the front surface 56a of the wafer 56 through the spray orifice 16a of the cleaning nozzle 16 that is being swung back and forth in the direction indicated by the arrow R4 above the wafer 56. Thus, the front surface 56a of the wafer 56 can be roughly cleaned and cleared of fallen abrasive grains from the cutting blade 78. The cleaning water supplied to the wafer 56 may be pure water from the high-pressure pure water source 20 alone, but is preferably a binary fluid mixture of pure water from the high-pressure pure water source 20 and high-pressure air from the high-pressure air source 26 in terms of achieving higher cleaning effect. The first cleaning time may be, for example, approximately 30 to 120 seconds.

Second cleaning The first cleaning is followed by second cleaning, where the front surface 56a of the wafer 56 is cleaned with the ammonia water supplied to the front surface 56a of the wafer 56 using the brush 30b. More specifically, the spinner table 4 is rotated in the direction indicated by the arrow R3 in FIG. 6 at a predetermined speed (e.g., 500 rpm). Then, the ammonia water is supplied to the front surface 56a of the wafer 56 through the spray orifice 30a of the ammonia water nozzle 30 that is being swung back and forth in the direction indicated by the arrow R5 above the wafer 56, while the front surface 56a of the wafer 56 is swept with the brush 30b. Thus, cutting chips that have adhered to the front surface 56a of the wafer 56 can be removed. In the present embodiment, since the front surface 56a of the wafer 56 is swept with the brush 30b while being cleaned with the ammonia water, it is possible to remove tiny cutting chips as small as 0.05 μm. The ammonia water supplied to the wafer 56 may be ammonia water from the ammonia water source 34 alone, but is preferably a binary fluid mixture of ammonia water from the ammonia water source 34 and high-pressure air from the high-pressure air source 40 in terms of achieving higher cleaning effect. The second cleaning time may be, for example, approximately 7 to 21 seconds.

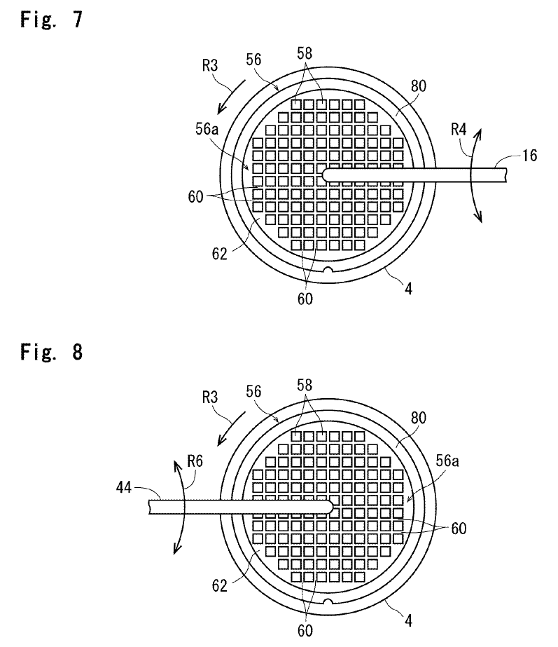

Third cleaning In the present embodiment, the second cleaning is followed by third cleaning, where the front surface 56a of the wafer 56 is finally cleaned with pure water supplied to the front surface 56a of the wafer 56. More specifically, the spinner table 4 is rotated in the direction indicated by the arrow R3 in FIG. 7 at a predetermined speed (e.g., 500 rpm). Then, the cleaning water is supplied to the front surface 56a of the wafer 56 through the spray orifice 16a of the cleaning nozzle 16 that is being swung back and forth in the direction indicated by the arrow R4 above the wafer 56. This can prevent the ammonia water from remaining on the front surface 56a of the wafer 56. The cleaning water supplied to the wafer 56 may be pure water from the high-pressure pure water source 20 alone, but is preferably a binary fluid mixture of pure water from the high-pressure pure water source 20 and high-pressure air from the high-pressure air source 26 in terms of achieving higher rinsing effect. The third cleaning time may be, for example, approximately 30 seconds.

Drying The third cleaning is preferably followed by drying, where the front surface 56a of the wafer 56 is dried with dry air supplied to the front surface 56a of the wafer 56. More specifically, the spinner table 4 is rotated in the direction indicated by the arrow R3 in FIG. 8 at a predetermined speed (e.g., 2000 rpm). Then, the dry air is supplied to the front surface 56a of the wafer 56 through a spray orifice 44a of the air nozzle 44 that is being swung back and forth in the direction indicated by the arrow R6 above the wafer 56. Thus, the front surface 56a of the wafer 56 can be dried. The drying time may be, for example, approximately 20 to 30 seconds.

As described above, in the present embodiment, the front surface 56a of the wafer 56 is cleaned first with the cleaning water supplied thereto and then with the ammonia water supplied thereto using the brush 30b, while the spinner table 4 is rotated, whereby the surface 56a of the wafer 56 can be sufficiently cleared of cutting chips.

Further, in the present embodiment, the second cleaning is conducted after fallen abrasive grains from the cutting blade 78 have been removed from the front surface 56a of the wafer 56 by the first cleaning with the cleaning water. Thus, there is no chance that the fallen abrasive grains from the cutting blade 78 are rubbed against the front surface 56a when it is swept with the brush 30b during the second cleaning, thereby preventing damage to the device region 62 caused by the abrasive grains.

### Reference Signs List

2 Cleaning apparatus 4 Spinner table 6 Cleaning water supply unit 8 Ammonia cleaning unit 16 Cleaning nozzle 16a Spray orifice of cleaning nozzle 30 Ammonia water nozzle 30a Spray orifice of ammonia water nozzle 30b Brush 56 Wafer 56a Front surface of wafer 56b Rear surface of wafer 58 Device 60 Division line 62 Device region 64 Chamfered portion 78 Cutting blade

What is claimed is:

1. A method for cleaning a wafer that has on its front surface a device region where a plurality of devices are demarcated by a division line, the method comprising:
mounting the wafer on a spinner table such that a rear surface of the wafer faces the spinner table and a front surface of the wafer is exposed, the spinner table being rotatable while holding the wafer;
subjecting the front surface of the wafer to first cleaning with cleaning water supplied to the front surface of the wafer, while rotating the spinner table; and
subjecting the front surface of the wafer to second cleaning with ammonia water supplied to the front surface of the wafer using a brush.

2. The method of claim 1, further comprising, after the second cleaning, subjecting the front surface of the wafer to third final cleaning with pure water supplied to the front surface of the wafer.

3. The method of claim 1, further comprising, before the first cleaning, removing a necessary amount of chamfered portion using a cutting blade, while supplying cutting water to the chamfered portion, the chamfered portion being formed on an outer periphery of the wafer to surround the device region.

4. A cleaning apparatus for performing the method of claim 1, the apparatus comprising:
the spinner table; a cleaning water supply unit including a cleaning nozzle that supplies the cleaning water to the front surface of the wafer held on the spinner table; and an ammonia cleaning unit that cleans the front surface of the wafer held on the spinner table with the ammonia water supplied to the front surface of the wafer using the brush.
